(19) United States
(12) Patent Application Publication
(10) Pub. No.: US 2026/0282919 A1
(43) Pub. Date: Sep. 17, 2026

(54) SEMICONDUCTOR DEVICE AND MANUFACTURING METHOD THEREOF

(71) Applicant: UNITED MICROELECTRONICS CORP., Hsin-Chu City (TW)

(72) Inventors: Chin-Chia Yang, Tainan City (TW); Da-Jun Lin, Kaohsiung City (TW); Fu-Yu Tsai, Tainan City (TW); Bin-Siang Tsai, Changhua County (TW)

(73) Assignee: UNITED MICROELECTRONICS CORP., Hsin-Chu City (TW)

(21) Appl. No.: 19/096,617

(22) Filed: Mar. 31, 2025

(30) Foreign Application Priority Data
Mar. 14, 2025 (TW) 114109644

(51) Int. Cl. H10W 42/00; H10W 74/01; H10W 74/10

(52) U.S. Cl. CPC H10W 42/121; H10W 74/01; H10W 74/147

(57) ABSTRACT

A semiconductor device includes a semiconductor substrate, pad structures, a filling dielectric layer, and a compressive stress layer. The pad structures and the filling dielectric layer are disposed on the semiconductor substrate, and the filling dielectric layer includes a first portion and a second portion. The first portion is disposed between the pad structures in a horizontal direction. The second portion is disposed above the pad structures in a vertical direction. The compressive stress layer is disposed on the filling dielectric layer and the pad structures. The second portion of the filling dielectric layer includes an opening located above one of the pad structures in the vertical direction, the opening is filled with the compressive stress layer, and a thickness of the compressive stress layer is greater than a thickness of the second portion of the filling dielectric layer.

### BACKGROUND OF THE INVENTION

### FIELD OF THE INVENTION

The present invention relates to a semiconductor device and a manufacturing method thereof, and more particularly, to a semiconductor device including a compressive stress layer and a manufacturing method thereof.

### DESCRIPTION OF THE PRIOR ART

Integrated circuit manufacturing process technology has been continuously improved with the advancement of science and technology for enabling various electronic circuits to be integrated and/or formed on a single chip. The semiconductor process for manufacturing wafers includes many steps, such as a deposition process to form a thin film, a photoresist coating, an exposure, and development process to form a patterned photoresist, and an etching process to pattern the thin film. During the processes, warpage may occur in the wafer due to the process conditions (such as but not limited to high temperature) and/or the materials with different characteristics formed and stacked on the wafer. The operation of the components on the wafer and/or the related process yield will be affected when the warpage issue is too serious.

### SUMMARY OF THE INVENTION

A semiconductor device and a manufacturing method thereof are provided in the present invention. An allocation of a compressive stress layer and a filling dielectric layer is used for improving a warpage issue of the semiconductor device.

According to an embodiment of the present invention, a semiconductor device is provided. The semiconductor device includes a semiconductor substrate, pad structures, a filling dielectric layer, and a compressive stress layer. The pad structures and the filling dielectric layer are disposed on the semiconductor substrate, and the filling dielectric layer includes a first portion and a second portion. The first portion is disposed between the pad structures in a horizontal direction, and the second portion is disposed above the pad structures in a vertical direction. The compressive stress layer is disposed on the filling dielectric layer and the pad structures. The second portion of the filling dielectric layer includes an opening located above one of the pad structures in the vertical direction, the opening is filled with the compressive stress layer, and a thickness of the compressive stress layer is greater than a thickness of the second portion of the filling dielectric layer.

According to an embodiment of the present invention, a manufacturing method of a semiconductor device is provided. The manufacturing method includes the following steps. A semiconductor substrate is provided. Pad structures and a filling dielectric layer are formed on the semiconductor substrate, and the filling dielectric layer includes a first portion and a second portion. The first portion is disposed between the pad structures in a horizontal direction, and the second portion is disposed above the pad structures in a vertical direction. A compressive stress layer is formed on the filling dielectric layer and the pad structures. The second portion of the filling dielectric layer includes an opening located above one of the pad structures in the vertical direction, the opening is filled with the compressive stress layer, and a thickness of the compressive stress layer is greater than a thickness of the second portion of the filling dielectric layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a semiconductor device according to an embodiment of the present invention.

FIGS. 2-6 are schematic drawings illustrating a manufacturing method of a semiconductor device according to an embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, and FIG. 6 is a schematic drawing in a step subsequent to FIG. 5.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and the scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

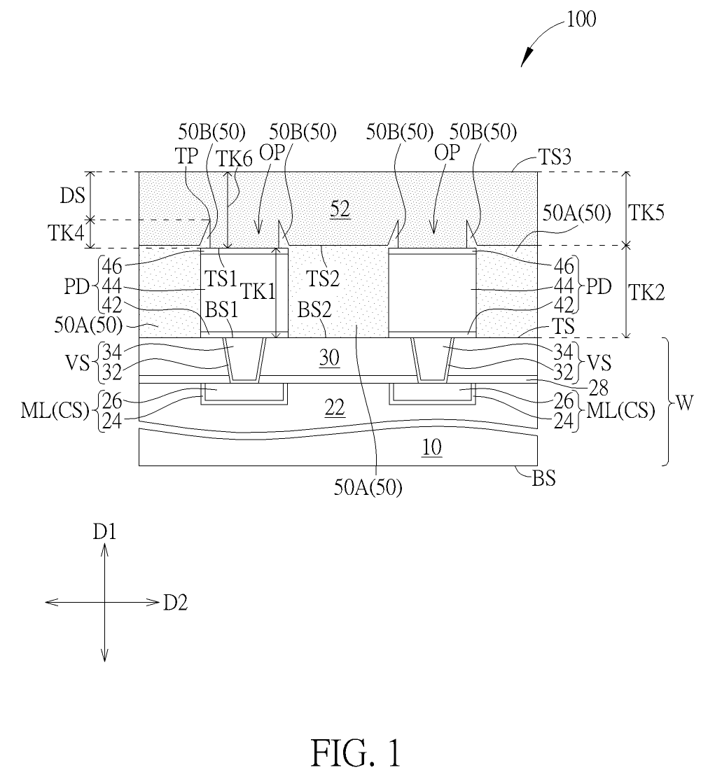

Please refer to FIG. 1. FIG. 1 is a schematic drawing illustrating a semiconductor device 100 according to an embodiment of the present invention. As shown in FIG. 1, the semiconductor device 100 includes a semiconductor substrate W, a plurality of pad structures PD, a filling dielectric layer 50, and a compressive stress layer 52. The pad structures PD and the filling dielectric layer 50 are disposed on the semiconductor substrate W, and the filling dielectric layer 50 includes a first portion 50A and a second portion 50B. The first portion 50A is disposed between the pad structures PD in a horizontal direction D2, and the second portion 50B is disposed above the pad structures PD in a vertical direction D1. The compressive stress layer 52 is disposed on the filling dielectric layer 50 and the pad structures PD. The second portion 50B of the filling dielectric layer 50 includes an opening OP located above one of the pad structures PD in the vertical direction D1, the opening OP is filled with the compressive stress layer 52, and a thickness of the compressive stress layer 52 (such as a thickness TK5 or a thickness TK6) is greater than a thickness of the second portion 50B of the filling dielectric layer 50 (such as a thickness TK4). The proportion of the compressive stress material in the material layers located above the pad structure PD may be increased relatively by the design of filling the opening with the compressive stress layer 52, and the warpage issue may be improved accordingly.

In some embodiments, the vertical direction D1 described above may be regarded as a thickness direction of the semiconductor substrate W, the semiconductor substrate W may have a top surface TS and a bottom surface BS opposite to the top surface TS in the vertical direction D1, and the pad structures PD, the filling dielectric layer 50, and the compressive stress layer 52 described above may be disposed at the side of the top surface TS. Horizontal directions substantially orthogonal to the vertical direction D1 (such as the horizontal direction D2 and other directions orthogonal to the vertical direction D1) may be substantially parallel with the top surface TS and/or the bottom surface BS of the semiconductor substrate W, but not limited thereto. In this description, a distance between the bottom surface BS of the semiconductor substrate W and a relatively higher location and/or a relatively higher part in the vertical direction D1 may be greater than a distance between the bottom surface BS of the semiconductor substrate W and a relatively lower location and/or a relatively lower part in the vertical direction D1. The bottom or a lower portion of each component may be closer to the bottom surface BS of the semiconductor substrate W in the vertical direction D1 than the top or upper portion of this component. Another component disposed above a specific component may be regarded as being relatively far from the bottom surface BS of the semiconductor substrate W in the vertical direction D1, and another component disposed under a specific component may be regarded as being relatively close to the bottom surface BS of the semiconductor substrate W in the vertical direction D1. In this description, a top surface and a top portion of a specific component may include the topmost surface and the topmost portion of this component in the vertical direction D1, respectively, and a bottom surface and a bottom portion of a specific component may include the bottommost surface and the bottommost portion of this component in the vertical direction D1, respectively. In this description, the condition that a certain component is disposed between two other components in a specific direction may include a condition that the certain component is sandwiched between the two other components in the specific direction. In addition, a thickness of a specific component in this description is generally a thickness of the specific component in the vertical direction D1, unless an addition description is accompanied.

In some embodiments, the semiconductor substrate W may include a substrate 10, a dielectric layer 22, an interconnection structure CS, a dielectric layer 28, a dielectric layer 30, and via conductors VS. The substrate 10 may include a silicon substrate or a substrate made of other suitable semiconductor materials or non-semiconductor materials. The dielectric layer 22 is disposed on the substrate 10, the interconnection structure CS is disposed in the dielectric layer 22, the dielectric layer 30 is disposed above the dielectric layer 22 and the interconnection structure CS, and the dielectric layer 28 is disposed between the dielectric layer 30 and the dielectric layer 22. The dielectric layer 22, the dielectric layer 28, and the dielectric layer 30 may include an oxide dielectric material (such as silicon oxide), a nitride dielectric material (such as silicon nitride), a carbide dielectric material (such as silicon carbide), a low dielectric constant (low-k) dielectric material (such as a dielectric material having dielectric constant lower than 2.7, but not limited thereto), or other suitable dielectric materials. The interconnection structure CS may include a plurality of electrically conductive lines (such as electrically conductive lines ML) and a plurality of via conductors (not illustrated) alternately disposed in the vertical direction D1 for forming the required connection paths. In some embodiments, the electrically conductive line ML may be regarded as the electrically conductive line located at the topmost layer in the interconnection structure CS, the via conductor VS may penetrate through the dielectric layer 30 and the dielectric layer 28, and each of the pad structures PD may be electrically connected with the interconnection structure CS through the corresponding via conductor VS. In some embodiments, the electrically conductive line ML may include a barrier layer 24 and an electrically conductive material 26 disposed on the barrier layer 24, the via conductor VS may include a barrier layer 32 and an electrically conductive material 34 disposed on the barrier layer 32, and the pad structure PD may include a barrier layer 42, a barrier layer 46, and an electrically conductive material 44 disposed between the barrier layer 42 and the barrier layer 46, but not limited thereto. The barrier layer 24, the barrier layer 32, the barrier layer 42, and the barrier layer 46 may include titanium nitride, tantalum nitride, or other suitable electrically conductive barrier materials. The electrically conductive material 26, the electrically conductive material 34, and the electrically conductive material 44 may include a material with relatively low electrical resistivity, such as copper, aluminum, tungsten or other suitable electrically conductive materials.

In some embodiments, some active components (such as transistors, and/or diodes), passive components (such as capacitors, and/or resistors), and/or other related circuits may be disposed on the substrate 10 according to some design considerations, and the pad structures PD may be electrically connected to the components and/or the circuits on the substrate 10 via the interconnection structure CS. In some embodiments, the semiconductor substrate W may include an image signal processor (ISP) or a semiconductor structure with other functions, and the pad structure PD may be regarded as the top metal electrically conductive structure formed on the image signal processor structure or other semiconductor structures. In addition, a thickness TK1 of each of the pad structures PD may be apparently greater than a thickness of the electrically conductive line in the interconnection structure CS (such as the electrically conductive line ML, but not limited thereto). For example, the thickness TK1 of each of the pad structures PD may be greater than 10,000 angstroms, such as being about 13,000 angstroms, but not limited thereto. Because the pad structure PD is relatively thick, the filling dielectric layer 50 with better gap- filling performance is required for filling the space between the pad structures PD. For example, the filling dielectric layer 50 may be formed by a high density plasma (HDP) deposition process, but not limited thereto. The high density plasma deposition process described above may include a high density chemical vapor deposition (HDP-CVD) process or other suitable deposition approaches, and the filling dielectric layer 50 may include a high density plasma (HDP) oxide dielectric material or other suitable filling dielectric materials. The compressive stress layer 52 may include a material capable of providing greater compressive stress, such as tetraethoxysilane (TEOS) oxide or other suitable high compressive stress materials. In some embodiments, the TEOS oxide may be formed by a chemical vapor deposition process, such as a plasma-enhanced CVD (PECVD) process, but not limited thereto. Because the gap-filling performance of the TOES oxide formed by PECVD is relatively poor, the filling dielectric layer 50 may be used to cover the pad structures PD first, and the compressive stress layer 52 with greater compressive stress may then be formed for improving the warpage issue. Therefore, a compressive stress of the compressive stress layer 52 may be greater than a compressive stress of the filling dielectric layer 50. For example, a compressive stress of the high density plasma oxide dielectric material described above may be about -136MPa, and a compressive stress of the TEOS oxide material described above may be about -370MPa, but not limited thereto. It is worth noting that, the value of compressive stress is generally negative to indicate that the object is squeezed, and in this description, when comparing the compressive stress of two different materials and/or layers, the comparison is made in terms of their absolute values.

In some embodiments, a bottom surface BS1 of each of the pad structures PD and a bottom surface BS2 of the first portion 50A of the filling dielectric layer 50 may be substantially coplanar, but not limited thereto. In addition, a top surface TS2 of the first portion 50A of the filling dielectric layer 50 and a top surface TS1 of each of the pad structures PD may be substantially coplanar or the top surface TS2 may be slightly higher than the top surface TS1 in the vertical direction D1. Therefore, a thickness TK2 of the first portion 50A of the filling dielectric layer 50 may be substantially equal to a thickness TK1 of each of the pad structures PD or the thickness TK2 may be slightly greater than the thickness TK1, and the top surface TS2 of the first portion 50A of the filling dielectric layer 50 is lower than a topmost part TP of the second portion 50B of the filling dielectric layer 50 in the vertical direction D1. The thickness TK1 may be equal to a distance between the bottom surface BS1 and the top surface TS1 in the vertical direction D1, and the thickness TK2 may be equal to a distance between the bottom surface BS2 and the top surface TS2 in the vertical direction D1. In addition, the second portion 50B of the filling dielectric layer 50 may be directly connected with the first portion 50A of the filling dielectric layer 50, the thickness TK4 of the second portion 50B may be equal to a distance between the topmost part TP of the second portion 50B and the top surface TS1 of the pad structure PD in the vertical direction D1, and a depth of the opening OP in the vertical direction D1 may be substantially equal to the thickness TK4. In some embodiments, the second portion 50B of the filling dielectric layer 50 located on each pad structure PD may include an opening OP located corresponding to this pad structure PD, and the second portion 50B of the filling dielectric layer 50 may include a plurality of openings OP located corresponding to the pad structures PD, respectively. Each of the openings OP may be completely filled with the compressive stress layer 52, and the compressive stress layer 52 disposed in the opening OP may directly contact the pad structure PD located corresponding to this opening OP. Additionally, the compressive stress layer 52 may cover the filling dielectric layer 50 an directly contact the first portion 50A and the second portion 50B of the filling dielectric layer 50.

In some embodiments, the size and the position of the opening OP may be controlled for reducing the second portion 50B of the filling dielectric layer 50 as much as possible without influencing the filling dielectric layer 50 between the pad structures PD, and the proportion of the compressive stress layer 52 in the material layers located above the pad structure PD may be increased relatively for improving the warpage issue. Therefore, the thickness of the compressive stress layer 52 is greater than the thickness TK4 of the second portion 50B of the filling dielectric layer 50, and the thickness TK4 of the second portion 50B of the filling dielectric layer 50 may be less than the thickness TK2 of the first portion 50A of the filling dielectric layer 50. In some embodiments, a top surface TS3 of the compressive stress layer 52 is higher than the topmost part TP of the second portion 50B of the filling dielectric layer 50 in the vertical direction D1, and a distance DS between the top surface TS3 of the compressive stress layer 52 and the topmost part TP of the second portion 50B of the filling dielectric layer 50 in the vertical direction D1 is greater than the thickness TK4 of the second portion 50B of the filling dielectric layer 50. The above-mentioned thickness of the compressive stress layer 52 may be equal to a distance between the top surface TS3 of the compressive stress layer 52 and the top surface TS2 of the first portion 50A of the filling dielectric layer 50 in the vertical direction D1 (such as being equal to the thickness TK5) or a distance between the top surface TS3 of the compressive stress layer 52 and the top surface TS1 of the pad structure PD in the vertical direction D1 (such as being equal to the thickness TK6), and the thickness of the compressive stress layer 52 may be less than the thickness TK2 of the first portion 50A of the filling dielectric layer 50, but not limited thereto.

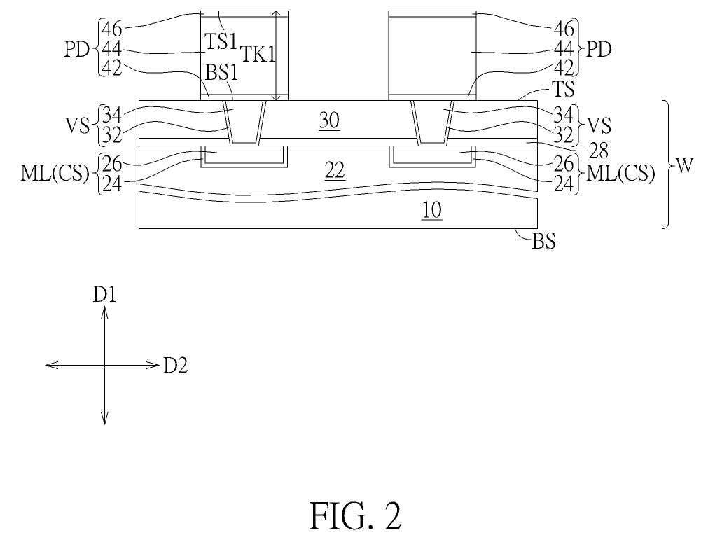

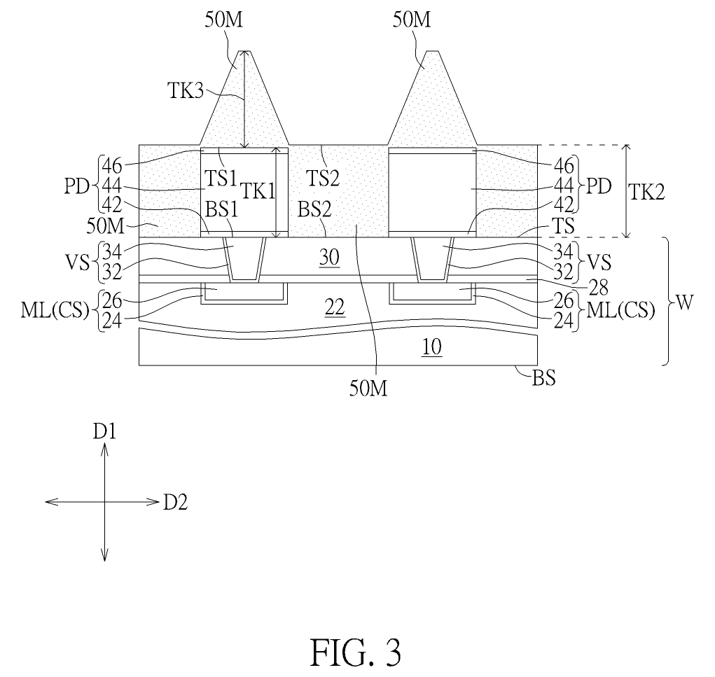

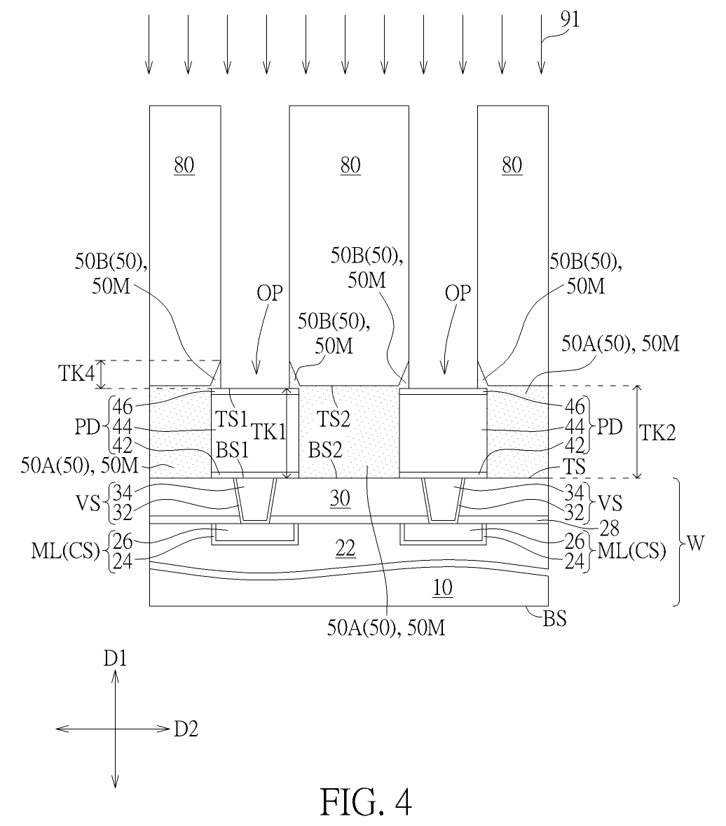

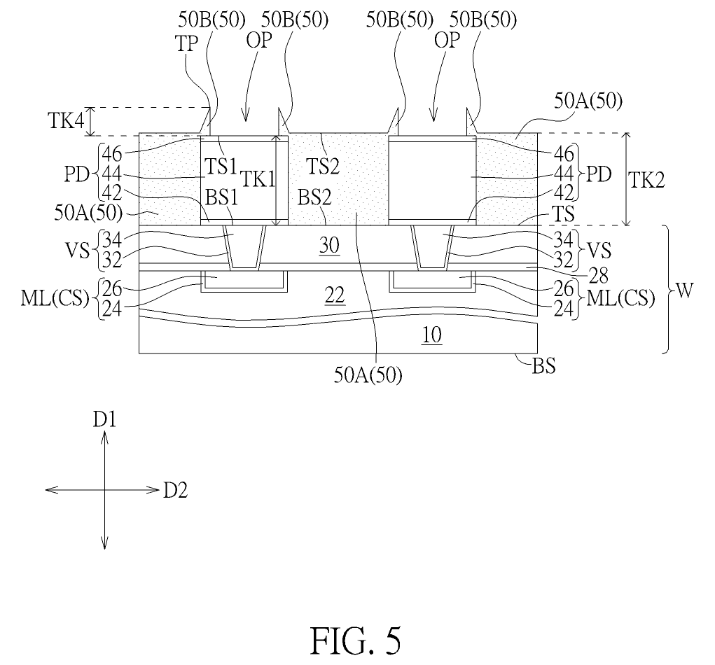

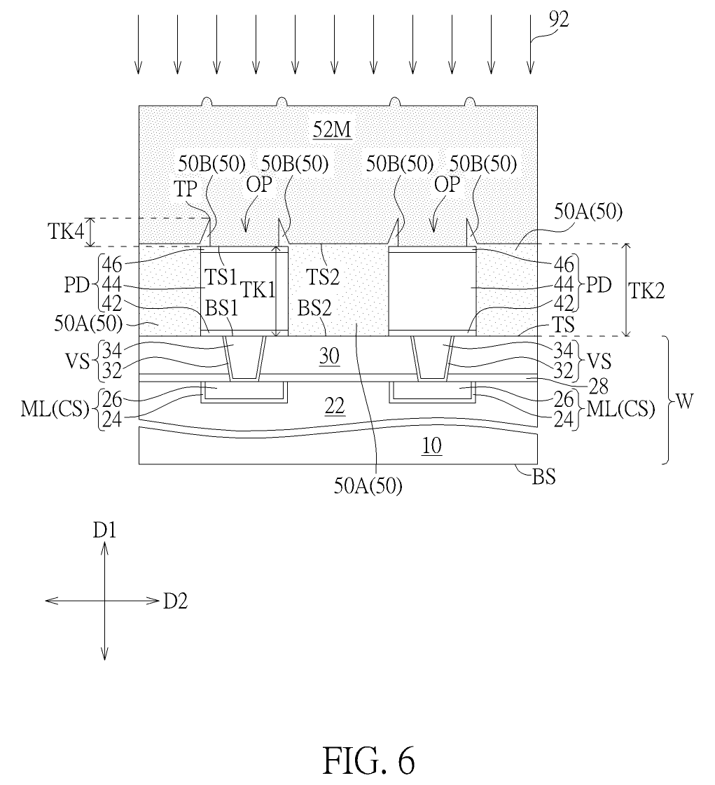

Please refer to FIGS. 1 and 2-6. FIGS. 2-6 are schematic drawings illustrating a manufacturing method of a semiconductor device according to an embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, and FIG. 6 is a schematic drawing in a step subsequent to FIG. 5. In some embodiments, FIG. 1 may be regarded as a schematic drawing in a step subsequent to FIG. 6, but not limited thereto. As shown in FIG. 1, the manufacturing method in this embodiment may include the following steps. Firstly, the semiconductor substrate W is provided. The pad structures PD and the filling dielectric layer 50 are formed on the semiconductor substrate W, and the filling dielectric layer 50 includes the first portion 50A and the second portion 50B. The first portion 50A is disposed between the pad structures PD in the horizontal direction D2, and the second portion 50B is disposed above the pad structures PD in the vertical direction D1. The compressive stress layer 52 is formed on the filling dielectric layer 50 and the pad structures PD. The second portion 50B of the filling dielectric layer 50 includes the opening OP located above one of the pad structures PD in the vertical direction D1, the opening OP is filled with the compressive stress layer 52, and the thickness of the compressive stress layer 52 (such as the thickness TK5 or the thickness TK6) is greater than the thickness TK4 of the second portion 50B of the filling dielectric layer 50.

Specifically, the manufacturing method in this embodiment may include but is not limited to the following steps. As shown in FIG. 2, the pad structures PD may be formed on the semiconductor substrate W, and each of the pad structures PD may include the barrier layer 42, the electrically conductive material 44, and the barrier layer 46 described above, but not limited thereto. Subsequently, as shown in FIG. 3, a filling dielectric material 50M may be formed on the semiconductor substrate W. The filling dielectric material 50M covers the pad structures PD, a portion of the filling dielectric material 50M is located between the pad structures PD in the horizontal direction D2, and another portion of the filling dielectric material 50M is located above the pad structures PD in the vertical direction D1. In some embodiments, the filling dielectric material 50M may be formed by the high density plasma deposition process, and because of the characteristics of this deposition process, a thickness TK3 of the filling dielectric material 50M located above the pad structures PD in the vertical direction D1 and the thickness TK2 of the filling dielectric material 50M located between the pad structures PD in the horizontal direction D2 may be substantially equal to each other, but not limited thereto. Subsequently, as shown in FIGS. 3-5, an etching process 91 may be performed to the filling dielectric material 50M located above the pad structures PD in the vertical direction D1, a part of the filling dielectric material 50M located above the pad structures PD may be removed by the etching process 91 for forming the opening OP, and the opening OP may expose one of the pad structures PD. In some embodiments, the openings OP may be formed on the corresponding pad structures PD, respectively, and each of the openings OP may expose the corresponding pad structure PD. In some embodiments, a patterned mask layer 80 may be formed on the filling dielectric material 50M and the etching process 91 may be performed with the patterned mask layer 80 as a mask, but not limited thereto. The patterned mask layer 80 may include patterned photoresist or other suitable mask materials, and the patterned mask layer 80 may be removed after the etching process 91.

After the etching process 91, the filling dielectric material 50M located above the pad structures PD becomes the second portion 50B of the filling dielectric layer 50, and the filling dielectric material 50M located between the pad structures PD becomes the first portion 50A of the filling dielectric layer 50. The filling dielectric material 50M located between the pad structures PD in the horizontal direction D2 may be covered by the patterned mask layer 80 in the etching process 91 without being etched accordingly. Therefore, the thickness of the filling dielectric material 50M located between the pad structures PD before the etching process 91 may be equal to the thickness of the first portion 50A of the filling dielectric layer 50 (such as both being the thickness TK2), and the thickness TK3 of the filling dielectric material 50M located above the pad structures PD before the etching process 91 may be greater than the thickness TK4 of the second portion 50B of the filling dielectric layer 50. It is worth noting that the method of forming the filling dielectric layer 50 in this embodiment may include but is not limited to the steps illustrated in FIGS. 3-5 described above, and the filling dielectric layer 50 including the openings OP may be formed by other suitable approaches according to some design considerations.

Subsequently, as shown in FIGS. 4-6, a compressive stress material 52M may be formed covering the pad structures PD and the filling dielectric layer 50 after the etching process 91, the openings OP may be filled with the compressive stress material 52M, and a compressive stress of the compressive stress material 52M is greater than that of the filling dielectric material 50M. In some embodiments, the compressive stress material 52M may include the TEOS oxide described above, and the compressive stress material 52M may be formed by a chemical vapor deposition process, such as a plasma-enhanced chemical vapor deposition process, but not limited thereto. Subsequently, as shown in FIGS. 6 and 1, a planarization process 92 may be performed to the compressive stress material 52M, and the compressive stress material 52M becomes the compressive stress layer 52 after the planarization process 92. The planarization process 92 may include a chemical mechanical polishing (CMP) process or other suitable planarization approaches. A part of the compressive stress material 52M may be removed by the planarization process 92, and the compressive stress material 52M remaining on the semiconductor substrate W after the planarization process 92 becomes the compressive stress layer 52 described above. The method of forming the compressive stress layer 52 in this embodiment may include but is not limited to the steps illustrated in FIG. 6 and FIG. 1 described above, and the compressive stress layer 52 shown in FIG. 1 may also be formed by other suitable approaches according to some design considerations. The compressive stress layer 52 may directly contact the pad structures PD, the first portion 50A of the filling dielectric layer 50, and the second portion 50B of the filling dielectric layer 50, and the thickness of the compressive stress layer 52 may be controlled by the planarization process 92 for avoiding the influence of the excessively thick compressive stress layer on other related processes.

To summarize the above descriptions, according to the semiconductor device and the manufacturing method thereof in the present invention, the proportion of the filling dielectric material in the material layers located above the pad structures may be reduced by the etching process described above, and the size and the position of the openings formed by the etching process may be controlled for reducing the filling dielectric material located above the pad structures in the vertical direction as much as possible without influencing the filling dielectric material between the pad structures. In addition, taking process capabilities (such as but not limited to alignment shifts) into consideration, some of the filling dielectric material has to remain above the pad structures after the etching process described above and becomes the second portion of the filling dielectric layer, and the second portion of the filling dielectric layer with the opening is formed by the manufacturing method in the present invention accordingly. The proportion of the compressive stress layer in the material layers located above the pad structures may be increased relatively by the design described above for improving the warpage issue.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a semiconductor substrate;
pad structures disposed on the semiconductor substrate;
a filling dielectric layer disposed on the semiconductor substrate, wherein the filling dielectric layer comprises:
a first portion disposed between the pad structures in a horizontal direction; and
a second portion disposed above the pad structures in a vertical direction; and
a compressive stress layer disposed on the filling dielectric layer and the pad structures, wherein the second portion of the filling dielectric layer comprises an opening located above one of the pad structures in the vertical direction, the opening is filled with the compressive stress layer, and a thickness of the compressive stress layer is greater than a thickness of the second portion of the filling dielectric layer.

2. The semiconductor device according to claim 1, wherein a compressive stress of the compressive stress layer is greater than a compressive stress of the filling dielectric layer.

3. The semiconductor device according to claim 1, wherein the compressive stress layer disposed in the opening directly contacts the one of the pad structures.

4. The semiconductor device according to claim 1, wherein the compressive stress layer directly contacts the first portion of the filling dielectric layer.

5. The semiconductor device according to claim 1, wherein a top surface of the compressive stress layer is higher than a topmost part of the second portion of the filling dielectric layer in the vertical direction.

6. The semiconductor device according to claim 5, wherein a distance between the top surface of the compressive stress layer and the topmost part of the second portion of the filling dielectric layer is greater than the thickness of the second portion of the filling dielectric layer.

7. The semiconductor device according to claim 1, wherein the thickness of the second portion of the filling dielectric layer is less than a thickness of the first portion of the filling dielectric layer.

8. The semiconductor device according to claim 1, wherein a top surface of the first portion of the filling dielectric layer is lower than a topmost part of the second portion of the filling dielectric layer in the vertical direction.

9. The semiconductor device according to claim 1, wherein a thickness of each of the pad structures is greater than 10,000 angstroms.

10. The semiconductor device according to claim 1, wherein the semiconductor substrate comprises an interconnection structure, and each of the pad structures is electrically connected with the interconnection structure.

11. A manufacturing method of a semiconductor device, comprising:
providing a semiconductor substrate;
forming pad structures on the semiconductor substrate;
forming a filling dielectric layer on the semiconductor substrate, wherein the filling dielectric layer comprises:
a first portion disposed between the pad structures in a horizontal direction; and
a second portion disposed above the pad structures in a vertical direction; and
forming a compressive stress layer on the filling dielectric layer and the pad structures, wherein the second portion of the filling dielectric layer comprises an opening located above one of the pad structures in the vertical direction, the opening is filled with the compressive stress layer, and a thickness of the compressive stress layer is greater than a thickness of the second portion of the filling dielectric layer.

12. The manufacturing method of the semiconductor device according to claim 11, wherein a method of forming the filling dielectric layer comprises:
forming a filling dielectric material on the semiconductor substrate, wherein the pad structures are covered by the filling dielectric material, a portion of the filling dielectric material is located between the pad structures in the horizontal direction, and another portion of the filling dielectric material is located above the pad structures in the vertical direction; and
performing an etching process to the filling dielectric material located above the pad structures in the vertical direction, wherein a part of the filling dielectric material located above the pad structures removed by the etching process for forming the opening exposing the one of the pad structures.

13. The manufacturing method of the semiconductor device according to claim 12, wherein the filling dielectric material located above the pad structures after the etching process becomes the second portion of the filling dielectric layer, and the filling dielectric material located between the pad structures after the etching process becomes the first portion of the filling dielectric layer.

14. The manufacturing method of the semiconductor device according to claim 13, wherein a thickness of the filling dielectric material located above the pad structures before the etching process is greater than the thickness of the second portion of the filling dielectric layer.

15. The manufacturing method of the semiconductor device according to claim 13, wherein a thickness of the filling dielectric material located between the pad structures before the etching process is equal to a thickness of the first portion of the filling dielectric layer.

16. The manufacturing method of the semiconductor device according to claim 12, wherein a method of forming the compressive stress layer comprises:
forming a compressive stress material covering the pad structures and the filling dielectric layer after the etching process; and
performing a planarization process to the compressive stress material, wherein the compressive stress material becomes the compressive stress layer after the planarization process.

17. The manufacturing method of the semiconductor device according to claim 12, wherein the filling dielectric material is formed by a high density plasma (HDP) deposition process.

18. The manufacturing method of the semiconductor device according to claim 11, wherein a compressive stress of the compressive stress layer is greater than a compressive stress of the filling dielectric layer.

19. The manufacturing method of the semiconductor device according to claim 11, wherein the compressive stress layer directly contacts the pad structures, the first portion of the filling dielectric layer, and the second portion of the filling dielectric layer.

20. The manufacturing method of the semiconductor device according to claim 11, wherein a distance between a top surface of the compressive stress layer and a topmost part of the second portion of the filling dielectric layer is greater than the thickness of the second portion of the filling dielectric layer.
